(19) United States
(12) Patent Application Publication
(10) Pub. No.: US 2006/0278975 A1
(43) Pub. Date: Dec. 14, 2006

(54) Ball grid array package with thermally-enhanced heat spreader

(75) Inventors: Pei-Haw Tsao, Tai-chung (TW); Chender Huang, Hsin-Chu (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/148,176

(22) Filed: Jun. 9, 2005

(51) Int. Cl. H01L 23/10

(52) U.S. Cl. 257/720

(57) ABSTRACT

A ball grid array (BGA) package having a thermally enhanced dummy chip is provided. In one embodiment, the package comprises a substrate. A chip is attached to the substrate. A heat spreader is disposed over the chip, and a dummy chip is disposed between the heat spreader and the chip. In one embodiment, the dummy chip is pre-attached to the heat spreader prior to placement in the BGA package. With the coefficient of thermal expansion (CTE) of the dummy chip being approximately equal to the CTE of the chip, the stress in the BGA package is reduced, thereby reducing interface delamination among the components of the BGA package.

### BACKGROUND

The present invention relates generally to ball grid array (BGA) packaging, and more specifically, to BGA packaging having mechanical enhancement, better thermal performance, and reduced warpage.

Ball grid array (BGA) is an advanced type of integrated circuit packaging technology which is characterized by the use of an organic substrate whose upper surface is mounted with a semiconductor chip and whose lower surface is mounted with a grid array of solder balls. During a surface mount technology process, for example, the BGA package can be mechanically bonded and electrically coupled to a printed circuit board (PCB) by means of these solder balls.

A conventional BGA package 10 with a heat spreader 12 is shown in FIG. 1. Due to heat produced by a chip 30, heat spreader 12 is employed in a molding compound 110 in BGA package 10 to dissipate the heat. Heat spreader 12 is attached to BGA package substrate 18 before a molding process to assemble the BGA package 10. The heat spreader is generally made out of a metal such as copper (Cu) for heat conduction and there is generally a gap between heat spreader 12 and chip 30 to accommodate the height of bond wires 32 that attach chip 30 to substrate 18. Prior art methods to maximize the efficiency of thermal dissipation of the heat spreader have included increasing the thickness of the heat spreader and using concave-shaped heat spreaders to minimize the gap between the heat spreader and the bond wires. These prior art approaches often induce higher stresses among chip 30, molding compound 110, and heat spreader 12 and these stresses typically lead to interface delamination among chip 30, molding compound 110, and heat spreader 12. Moreover, the small gap from concave-shaped heat spreaders may cause bond wire shorts and damage during heat spreader attachment.

Furthermore, due to the inherent coefficient of thermal expansion (CTE) mismatches between chip 30, substrate 18, underfill 50 (an adhesive flowed between chip 30 and substrate 18), and molding compound 110, high package warpage and thermal stresses are frequently induced in the BGA package. These high thermal stresses and warpage may cause delamination among the chip 30, molding compound 110, substrate 18, and heat spreader 12, and may also cause solder bump cracks leading to failure, thereby degrading the long term operating reliability of the BGA package.

For these reasons and other reasons that will become apparent upon reading the following detailed description, there is a need for an improved BGA package that reduces and/or eliminates the component and/or board level reliability problems associated with conventional BGA packages.

### SUMMARY

The present invention is directed to a ball grid array (BGA) package having a thermally enhanced dummy chip. In one embodiment, the package comprises a substrate. A chip is attached to the substrate. A heat spreader is disposed over the chip, and a dummy chip is disposed between the heat spreader and the chip. In one embodiment, the dummy chip is pre-attached to the heat spreader prior to placement in the BGA package. With the coefficient of thermal expansion (CTE) of the dummy chip being approximately equal to the CTE of the chip, the stress in the BGA package is reduced, thereby reducing interface delamination among the components of the BGA package.

### BRIEF DESCRIPTION OF THE DRAWINGS

The features, aspects, and advantages of the present invention will become more fully apparent from the following detailed description, appended claims, and accompanying drawings in which:

FIG. 1 is a cross-sectional view of a conventional semi-finished ball grid array package.

FIG. 2 is a cross-sectional view of a semi-finished ball grid array package according to aspects of the present disclosure.

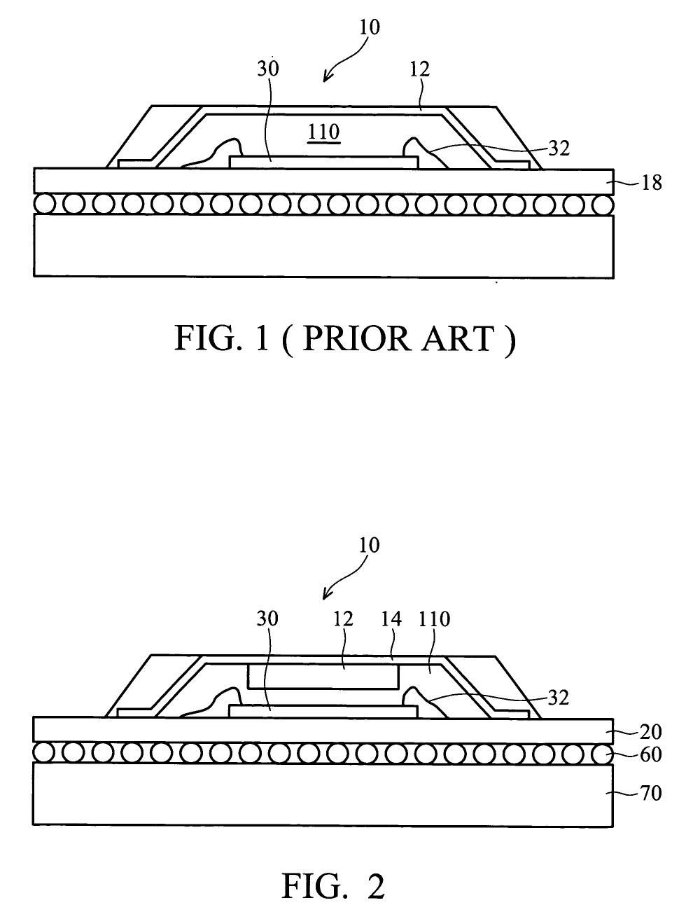

### DETAILED DESCRIPTION

In the following description, numerous specific details are set forth to provide a thorough understanding of the present invention. However, one having an ordinary skill in the art will recognize that the invention can be practiced without these specific details. In some instances, well-known structures and processes have not been described in detail to avoid unnecessarily obscuring the present invention.

Reference will now be made in detail to the present preferred embodiments of the present invention, examples of which are illustrated in the accompanying drawings.

Referring to FIG. 2, illustrated is a side view diagram of a semi-finished ball grid array (BGA) package 10 according to one embodiment of the present invention. BGA package 10 includes a semiconductor device 30 such as an integrated circuit chip (hereinafter referred to as chip 30). Chip 30 is secured to a first substrate 20 underlying chip 30. First substrate 20 may be an inorganic substrate and may include, for example, a ceramic-containing substrate such as Al₂O₃. Chip 30 is electrically connected to first substrate 20 via bonding wires 32. Although bonding wires 32 are employed to electrically couple chip 30 to first substrate 20, any means for coupling the chip to the substrate such as by way of solder bumps as known to those skilled in the art are within the scope of the present disclosure.

A set of solder balls 60 may be secured to contact pads (not shown) on the lower surface of first substrate 20. The set of solder balls 60 may also be secured to contact pads (not shown) on a second substrate 70, which may be a printed wire board (also sometimes called a printed circuit board) or may be a multilayer module known to those skilled in the art.

The BGA package 10 also includes a heat spreader 14 for enhancing the package's thermal performance. Heat spreader 14 is mounted above chip 30 and counter-balances the forces exerted by the thermal expansion mismatches between at least the chip 30 and the first substrate 20. Heat spreader 14 defines a cavity within which chip 30 is coupled to first substrate 20, this cavity is substantially filled with a molding compound 110 such as thermo-set epoxy.

Heat spreader 14 may comprise materials having relatively high coefficients of thermal expansion. In one embodiment, heat spreader 14 comprises copper tungsten, aluminum silicon carbide, aluminum, stainless steel, copper, nickel and/or nickel-plated copper. Other materials may be implemented accordingly to meet the design requirements of a particular application.

The BGA package 10 also includes a thermally enhanced dummy chip 12. Dummy chip 12 acts as a heat sink conducting heat away from chip 30 and for reducing warpage of the package 10 caused by thermal expansion mismatches between at least the chip 30, first substrate 20, heat spreader 14, and molding compound 110 thereby enhancing the structural integrity of the package. Dummy chip 12 is disposed between heat spreader 12 and chip 30 and is so dimensioned as to accommodate the height of bonding wires 32. In one embodiment, dummy chip 12 comprises a metal such as, for example copper. In another embodiment, dummy chip 12 comprises silicon. In yet another embodiment, dummy chip 12 comprises a thermally conductive material having high coefficients of thermal expansion so that package 10 will have high thermal performance. In one embodiment, the dummy chip 12, chip 30 and heat spreader 14 are fully encapsulated with molding compound 110.

Dummy chip 12 has a coefficient of thermal expansion approximately equal to the coefficient of thermal expansion of the chip 30. In one embodiment, the coefficients of thermal expansion of the dummy chip 12 and chip 30 are substantially equal to the coefficient of thermal expansion of molding compound 110 so that stress in BGA package 10 are reduced, thereby reducing the occurrence of interface delamination among chip 30, molding compound 110, and heat spreader 14. It is understood that the material, shape, and thickness of dummy chip 12 may be adjusted to match either the CTE of the chip 30, substrate 20, molding compound 110, or heat spreader 14 to meet the design criteria for a particular application.

In one embodiment, dummy chip 12 is pre-attached to the heat spreader 12 prior to their placement in the BGA package 10 by an adhesive, such as, for example epoxy. The adhesive preferably is chosen to match or accommodate the coefficient of thermal expansion of the dummy chip 12 and heat spreader 14.

The ball grid array package 10 of the present invention may have improved component and board level reliability when compared with conventional chip packages.

In the preceding detailed description, the present invention is described with reference to specifically exemplary embodiments thereof It will, however, be evident that various modifications, structures, processes, and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

What is claimed is:

1. An integrated circuit chip package, comprising:
a substrate;
a chip attached to the substrate;
a heat spreader disposed over the chip; and
a dummy chip disposed between the heat spreader and the chip.

2. The integrated circuit chip package of claim 1, wherein the dummy chip is attached to the heat spreader.

3. The integrated circuit chip package of claim 2, wherein the dummy chip is attached to the heat spreader by an adhesive.

4. The integrated circuit chip package of claim 1, wherein the chip, heat spreader, and dummy chip are substantially encapsulated with a molding compound.

5. The integrated circuit chip package of claim 4, wherein the coefficients of thermal expansion (CTE) of the dummy chip and the chip are substantially equal to the CTE of the molding compound.

6. The integrated circuit chip package of claim 1, wherein the dummy chip comprises metal.

7. The integrated circuit chip package of claim 1, wherein the dummy chip comprises silicon.

8. The integrated circuit chip package of claim 1, wherein the dummy chip comprises a material being thermally conductive.

9. The integrated circuit chip package of claim 1, wherein the coefficient of thermal expansion (CTE) of the dummy chip is approximately equal to the coefficient of thermal expansion of the chip.

10. The integrated circuit chip package of claim 1, wherein a material, shape, and thickness of the dummy chip may be adjusted to match the coefficient of thermal expansion of the chip.

11. The integrated circuit chip package of claim 1, wherein a material, shape, and thickness of the dummy chip may be adjusted to match the coefficient of thermal expansion of the heat spreader.

12. The integrated circuit chip package of claim 1, wherein a material, shape, and thickness of the dummy chip may be adjusted to match the coefficient of thermal expansion of the chip and the heat spreader.

13. A method for making a ball grid array package (BGA), comprising:
providing a chip attached to a substrate;
providing a heat spreader disposed over the chip; and
providing a dummy chip disposed between the heat spreader and the chip.

14. The method of claim 13, wherein the dummy chip is attached to the heat spreader.

15. The method of claim 13, wherein the chip, heat spreader, and dummy chip are substantially encapsulated with a molding compound and the coefficients of thermal expansion (CTE) of the dummy chip and the chip are substantially equal to the CTE of the molding compound.

16. The method of claim 13, wherein the dummy chip comprises metal.

17. The method of claim 13, wherein the dummy chip comprises silicon.

18. The method of claim 13, wherein the dummy chip comprises a material being thermally conductive.

19. The method of claim 13, wherein the coefficient of thermal expansion (CTE) of the dummy chip is approximately equal to the coefficient of thermal expansion of the chip.

20. The method of claim 13, wherein a material, shape, and thickness of the dummy chip may be adjusted to match the coefficient of thermal expansion of the chip and the heat spreader.
